(19) United States
(12) Patent Application Publication
(10) Pub. No.: US 2009/0021261 A1
(43) Pub. Date: Jan. 22, 2009

(54) Rf trap tuned by selectively inserting electrically conductive tuning elements

(75) Inventors: Thomas Chmielewski, Willoughby Hills, OH (US); William O. Braum, Twinsburg, OH (US); John T. Carlon, Madison, OH (US)

Correspondence Address: PHILIPS INTELLECTUAL PROPERTY & STANDARDS, 595 MINER ROAD, CLEVELAND, OH, 44143, US

(73) Assignee: Koninklijke Philips Electronics NV, Eindhoven (NL)

(21) Appl. No.: 10/597,018

(22) PCT Filed: Jan. 5, 2005
(86) PCT No.: PCT/IB05/50049

§ 371 Date: Jul. 6, 2006

Related U.S. Application Data
(60) Provisional application No. 60/536,355, filed on Jan. 14, 2004.

(51) Int. Cl. G01R 33/36

(52) U.S. Cl. 324/322

(57) ABSTRACT

A magnetic resonance imaging scanner (10) includes a main magnet (20) generating a spatially uniform main magnetic field at least over a field of view, a plurality of gradient coils (30) selectively generating magnetic field gradients at least over the field of view, and a radio frequency coil (32, 34) for performing at least one of exciting and detecting magnetic resonance at the selected resonance frequency in an imaging subject disposed in the field of view. A radio frequency trap (60, 60′) connected with the radio frequency coil (32, 34) includes helically grooved dielectric formers (62, 62) around which a coaxial cable (64) is wrapped. A plurality of electrically conductive tuning elements such as screws or rods (84, 90) are selectively inserted into the dielectric formers (62, 62) to tune the radio frequency trap (60, 60) to a selected resonance frequency by adjusting the inductance of the trap.

The following relates to the radio frequency arts. It finds particular application in magnetic resonance imaging scanners, and will be described with particular reference thereto. However, it also finds other radio frequency applications.

In magnetic resonance imaging scanners, the radio frequency coil typically is connected with a radio frequency trap to provide common mode high impedance to radio frequency current flow. In one common configuration, the radio frequency trap is a balanced butterfly trap including two dielectric formers or bobbins. A coaxial cable is wrapped around the two dielectric formers to define an inductive element. In the balanced butterfly topology, the cable is wrapped in oppositely directed helices on the two formers to produce oppositely directed magnetic fields in the two formers. The oppositely directed helical wrapping provides external field cancellation which is advantageous since the radio frequency trap is typically disposed relatively close to the radio frequency coil and inside the high magnetic field environment. A capacitance is connected across the shield conductor of the inductive element to form a resonant LC circuit having a resonance frequency:

$${ω}_{res} = \frac{1}{\sqrt{LC}} , \qquad ( 1 )$$

where L is the inductance of the inductive element formed by the wrapping of the cable around the dielectric formers, C is the capacitance value, and ωᵣₑₛ is the resonant frequency of the radio frequency trap.

One difficulty in constructing radio frequency traps is fine tuning of the resonant frequency ωᵣₑₛ to closely match the magnetic resonance frequency. The magnetic resonance frequency is typically in the tens or hundreds of megahertz. For example, at a main B₀ magnetic field of 3.0 Tesla, the resonance frequency is about 128 MHz. Commercial discrete fixed-value capacitors are not readily available with sufficiently narrow tolerances to ensure the trap has the desired resonant frequency without fine tuning of the resonance frequency ωᵣₑₛ.

In one approach to fine tuning, different fixed-value capacitors are tested in the butterfly trap. Since the capacitance value varies substantially from capacitor to capacitor (for example, commercial capacitors have a typical tolerance of about 5%), some capacitors may produce resonance closer to the desired resonance frequency than others. This approach has a number of drawbacks. It necessitates maintaining a large supply of capacitors for testing. Even with a large supply of capacitors, however, the possibility exists that no capacitor on hand will provide the desired resonant frequency. Moreover, a high degree of manual labor is involved in soldering and desoldering capacitors during the fine tuning process.

In another approach, a variable capacitor is used. The variable capacitor is readily adjusted to provide fine tuning. However, high power variable capacitors are large and bulky, which is problematic given the premium placed on space within a magnetic resonance imaging scanner housing and bore. Variable capacitors are also expensive.

In some radio frequency traps, tuning is achieved by adjusting a spacing of the cable windings. However, adjusting the windings is labor intensive and time consuming, and the adjusted windings can break the butterfly trap symmetry and reduce advantageous external field canceling. Moreover, changes in the adjusted winding spacing over time due to vibrations, magnetic forces, or other influences can cause detuning of the radio frequency trap.

The present invention contemplates an improved apparatus and method that overcomes the aforementioned limitations and others.

According to one aspect, a method is provided for tuning a radio frequency trap having an inductive element including a dielectric former and a coaxial cable wrapped around the former. An effective amount of electrically conductive material is inserted into the dielectric former, the amount being effective to adjust an inductance of the inductive element to tune the radio frequency trap to a selected resonant frequency value.

According to another aspect, a radio frequency trap is disclosed, including one or more dielectric formers. At least a portion of a cable including an inner conductor and a coaxial outer conductor is wrapped around the one or more dielectric formers. The coaxial outer conductor of the portion of the cable wrapped around the one or more dielectric formers defines at least one inductive element A capacitance is connected across the at least one inductive element. A selected amount of electrically conductive material is inserted into the one or more dielectric formers. The selected amount of electrically conductive material cooperates with the at least one inductive element and the capacitance to define a resonant circuit having a selected resonance frequency.

According to yet another aspect, an apparatus is disclosed, including a radio frequency trap. The radio frequency trap includes an even number of dielectric formers, a coaxial cable wrapped around the dielectric formers, and a plurality of tuning elements selectively inserted into the dielectric formers to tune the radio frequency trap to a selected resonance frequency.

According to still yet another aspect, a radio frequency trap is disclosed. At least a portion of a cable including an inner conductor and a coaxial outer conductor is wrapped around one or more dielectric formers. The coaxial outer conductor of the portion of the cable wrapped around the one or more dielectric formers defines at least one inductive element. A capacitance is connected across the at least one inductive element. One or more electrically conductive fasteners secure the one or more dielectric formers to a substrate. At least a portion of each electrically conductive fastener is disposed inside the dielectric former to which it fastens.

One advantage resides in simplified tuning of a radio frequency trap.

Another advantage resides in reduced cost of a tuned radio frequency trap.

Yet another advantage resides in precise tuning of a radio frequency trap.

Still yet another advantage is fixed positioning of the windings of a butterfly trap which reduces the likelihood of detuning due to changes in spacing of the windings due to vibrational, magnetic, or other influences.

Numerous additional advantages and benefits will become apparent to those of ordinary skill in the art upon reading the following detailed description of the preferred embodiments.

The invention may take form in various components and arrangements of components, and in various process operations and arrangements of process operations. The drawings are only for the purpose of illustrating preferred embodiments and are not to be construed as limiting the invention.

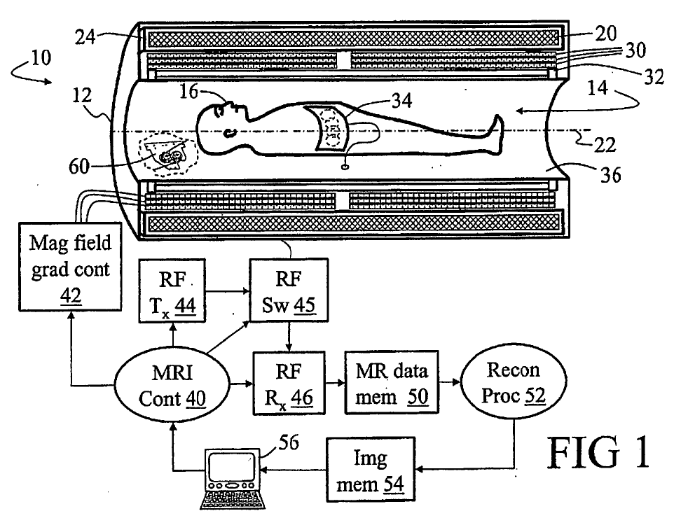

FIG. 1 shows a diagrammatic representation of a magnetic resonance imaging system including a radio frequency butterfly trap.

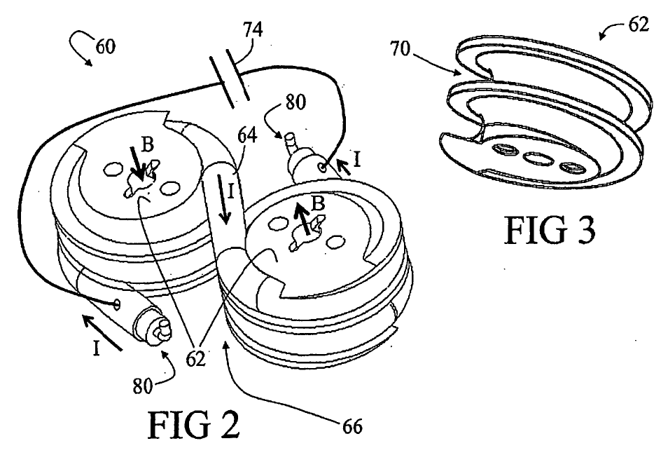

FIG. 2 shows a perspective view of the radio frequency butterfly trap of FIG. 1.

FIG. 3 shows a perspective view of one of the bobbins of the radio frequency butterfly trap of FIG. 2.

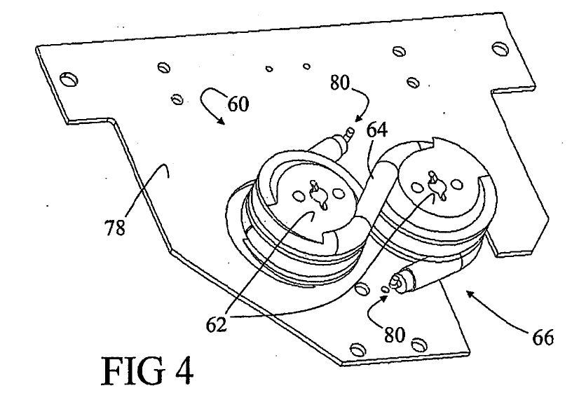

FIG. 4 shows a perspective view of the radio frequency butterfly trap of FIG. 2 mounted to a board with a printed circuit capacitor disposed on the board.

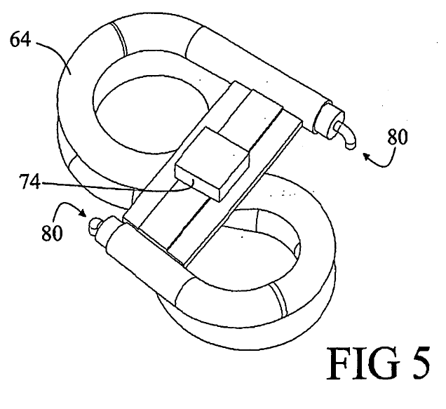

FIG. 5 shows a perspective view of a chip capacitor connected to the coaxial cable of the radio frequency butterfly trap of FIG. 2.

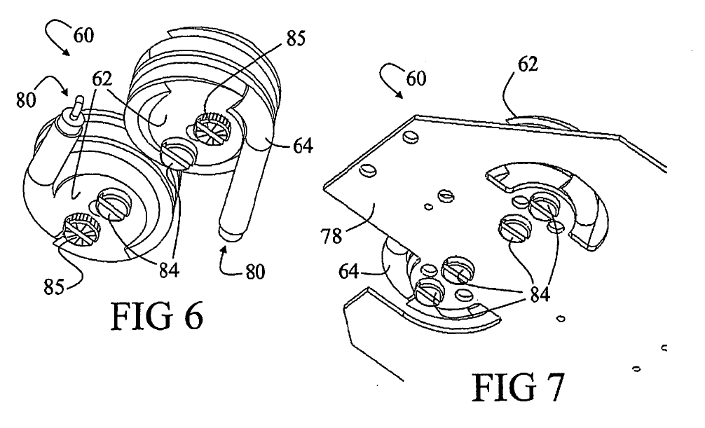

FIG. 6 shows a perspective view of the radio frequency butterfly trap of FIG. 2 with one tuning screw inserted into each bobbin, and one non-electrically conductive screw inserted for mechanical fastening.

FIG. 7 shows a perspective view of the radio frequency butterfly trap of FIG. 2 with two tuning screws inserted into each bobbin, in which the tuning screws also serve as fasteners for securing the radio frequency butterfly trap to a board.

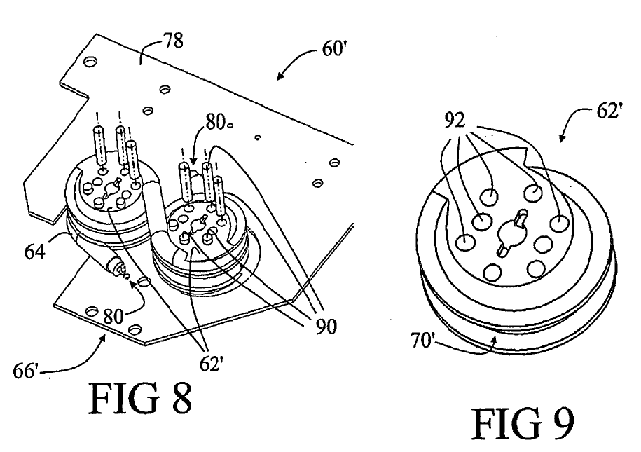

FIG. 8 shows a perspective view of another embodiment of the radio frequency butterfly trap, in which tuning rods are employed, mounted to a board. In FIG. 8, one half of the tuning-rods are inserted, while the other half of the tuning rods are shown aligned for insertion into the bobbins.

FIG. 9 shows a perspective view of one of the bobbins of the radio frequency butterfly trap of FIG. 8.

With reference to FIG. 1, a magnetic resonance imaging scanner 10 includes a housing 12 defining a generally cylindrical scanner bore 14 inside of which an associated imaging subject 16 is disposed. Main magnetic field coils 20 are disposed inside the housing 12, and produce a main B₀ magnetic field directed generally along and parallel to a central axis 22 of the scanner bore 14. The main magnetic field coils 20 are typically superconducting coils disposed inside cryoshrouding 24, although resistive main magnets can also be used.

The housing 12 also houses or supports magnetic field gradient coils 30 for selectively producing magnetic field gradients parallel to the central axis 22 of the bore 14, transverse to the central axis 22, or along other selected directions. The housing 12 further houses or supports a radio frequency body coil 32 for selectively exciting and/or detecting magnetic resonances. A coil array 34 disposed inside the bore 14 includes a plurality of coils, specifically four coils in the example coil array 34, although other numbers of coils can be used. The coil array 34 can be used as a phased array of receivers for parallel imaging, as a sensitivity encoding (SENSE) coil for SENSE imaging, or the like. In one embodiment, the coil array 34 is an array of surface coils disposed close to the imaging subject 16. The housing 12 typically includes a cosmetic inner liner 36 defining the scanner bore 14.

The coil array 34 can be used for receiving magnetic resonances that are excited by the whole body coil 32, or the magnetic resonances can be both excited and received by the coil array 34. Moreover, it is also contemplated to excite magnetic resonance with the coil array 34 and detect the magnetic resonance with the whole body coil 32. It will be appreciated that if one of the coils 32, 34 is used for both transmitting—and receiving, then the other one of the coils 32, 34 is optionally omitted.

The main magnetic field coils 20 produce a main magnetic field B₀. A magnetic resonance imaging controller 40 operates magnetic field gradient controllers 42 to selectively energize the magnetic field gradient coils 30, and operates a radio frequency transmitter 44 coupled to the radio frequency coil 32 or to the coils array 34 via a radio frequency switch 45 to selectively energize the radio frequency coil or coil array: 32, 34. By selectively operating the magnetic field gradient coils 30 and the radio frequency coil 32 or coil array 34 magnetic resonance is generated and spatially encoded in at least a portion of a region of interest of the imaging subject 16. By applying selected magnetic field gradients via the gradient coils 30, a selected k-space trajectory is traversed, such as a Cartesian trajectory, a plurality of radial trajectories, or a spiral trajectory. Alternatively, imaging data can be acquired as projections along selected magnetic field gradient directions. During a readout phase of imaging data acquisition, the magnetic resonance imaging controller 40 operates the switch 45 to couple a radio frequency receiver 46 to the coils array 34 or the whole body coil 32, to acquire magnetic resonance samples that are stored in a magnetic resonance data memory 50.

The imaging data are reconstructed by a reconstruction processor 52 into an image representation. In the case of k-space sampling data, a Fourier transform-based reconstruction algorithm can be employed. Other reconstruction algorithms, such as a filtered backprojection-based reconstruction, can also be used depending upon the format of the acquired magnetic resonance imaging data. For SENSE imaging data, the reconstruction processor 52 reconstructs folded images from the imaging data acquired by each coil, and then combines the folded images along with coil sensitivity parameters to produce an unfolded reconstructed image.

The reconstructed image generated by the reconstruction processor 52 is stored in an image memory 54, and can be displayed on a user interface 56, stored in non-volatile memory, transmitted over a local intranet or the Internet, viewed, stored, manipulated, or so forth. The user interface 56 can also enable a radiologist, technician, or other operator of the magnetic resonance imaging scanner 10 to communicate with the magnetic resonance imaging controller 40 to select, modify, and execute magnetic resonance imaging sequences.

With continuing reference to FIG. 1 and with further reference to FIGS. 2-7, a butterfly trap or balun 60 (revealed in FIG. 1 by partial cutaway of the housing 12) is inserted-on the line connecting the radio frequency switch 45 with the coil 32, 34. The butterfly trap or balun 60 provides a common mode high impedance to radio frequency current flow. As shown in FIG. 2, the radio frequency trap 60 includes a pair of generally cylindrical dielectric formers or bobbins 62 around which is wrapped a coaxial cable 64. The coaxial cable is wrapped around the formers 62 in opposite directions so that when a reference electric current “I” flows in the cable 64 in the direction indicated in FIG. 2, oppositely directed reference magnetic fields “B” are produced in the two formers 62. Thus, the portions of the cable 64 wrapped around the dielectric formers 62 define an inductive element 66 comprising two inductors electrically connected in series. The reference electric current “I” and reference magnetic fields “B” show the relative relationship between current and magnetic fields; however, the directions of the electric current and magnetic field switch back-and-forth at radio frequencies.

In one embodiment, each dielectric former or bobbin 62 includes a corkscrew slot or helical groove 70 (best seen in FIG. 3) formed on the cylindrical surface of the dielectric former 62. The coaxial cable 64 is received by the corkscrew slot 70 to provide alignment and determine spacing of the coils of the coaxial cable 64 on the dielectric formers 62. In another embodiment (not illustrated), the corkscrew slot 70 is omitted.

A capacitor 74 is connected across the inductive element 66 to define an LC resonant circuit. More specifically, the capacitor 74 is connected across ends of a shield conductor of the coaxial cable 64. The capacitor 74 is shown diagrammatically in FIG. 2 using a capacitor circuit symbol. In one embodiment, the butterfly trap 60 is secured to a printed circuit board 78 (shown in FIGS. 4 and 7), and the capacitor 74 is a chip capacitor (shown in FIG. 5). Ends of the cable 64 are stripped to form connection ends 80 for connection with the printed circuit board 78, for connection with cabling of one or both radio frequency coils 32, 34, or for connection elsewhere in the radio frequency energizing or detection circuitry. While the printed circuit board 78 is illustrated as supporting only the butterfly trap 60, it is to be appreciated that additional radio frequency circuitry or other electronics can be fabricated on, supported by, and/or interconnected via the printed circuit board 78.

The butterfly trap 60 has a resonant frequency related to the inductance of the inductive element 66 and the capacitance of the capacitor 74. For a simple parallel LC resonant circuit topology, the butterfly trap 60 has a resonant frequency ωₜᵣₐₚ in accordance with Equation (1), that is, ωₜᵣₐₚ=(LC)^{-0.5} where L is the inductance of the inductive element 66 and C is the capacitance of the capacitor 74. It is also contemplated to employ other resonant circuit topologies, for which the resonant frequency may have a different functional dependence upon the inductance of the inductive element or elements.

Typically, the capacitor 74 is a commercial capacitor having a nominal capacitance that generally varies within a specified tolerance. For example, the capacitance may have a 5% tolerance. Similarly, the inductive element 66 formed by winding the coaxial cable 64 on the bobbins 62 has a certain typical tolerance related to factors such as reproducibility of the spacing of the cable windings, reproducibility of the density and shape of the bobbins 62, and the like. These tolerances in capacitance and inductance lead to a corresponding tolerance of the resonant frequency of the butterfly trap, which tolerance may be too large to ensure precise tuning of the trap respective to the magnetic resonance frequency or other desired resonance frequency.

In order to fine tune the butterfly trap 60 to the magnetic resonance frequency or to another desired radio frequency resonance value, the capacitance is fixed and the inductance of the inductive element 66 is adjusted to achieve the target resonance frequency. The inductance is adjusted with electrically conductive material inserted into the formers 62. In the embodiment illustrated in FIGS. 2-7, the electrically conductive material is in the form of electrically conductive fasteners, such as electrically conductive screws 84 (shown in FIGS. 6 and 7) that screw into the formers 62 to secure the formers 62 and hence the butterfly trap 60 to the printed circuit board 78.

In one embodiment, the radio frequency trap 60 is disposed in the main B₀ magnetic field. In this embodiment, the electrically conductive screws 84 are suitably non-ferromagnetic. Insertion of non-ferromagnetic conductive material into the dielectric formers 62 effectively lowers the inductance of the inductive element 66. Thus, in accordance with ωₜᵣₐₚ=(LC)^{-0.5} the reduced inductance L causes an increase in the butterfly trap resonant frequency ωₜᵣₐₚ. As more non-ferromagnetic conductive material is inserted into the dielectric formers 62, the trap resonant frequency ωₜᵣₐₚ increases. In this embodiment, the capacitance of the capacitor 74 should be selected to be large enough to ensure that the trap resonant frequency is smaller than the desired trap resonant frequency value before insertion of any non-ferromagnetic conductive material into the formers 62.

In another embodiment, the radio frequency trap 60 is disposed outside of the main B₀ magnetic field. In this embodiment, the electrically conductive screws 84 can be non-ferromagnetic, as before, or they can be ferromagnetic. Insertion of ferromagnetic conductive material into the dielectric formers 62 effectively raises the inductance of the inductive element 66. Thus, in accordance with ωₜᵣₐₚ=(LC)^{-0.5} the increased inductance L causes a reduction in the butterfly trap resonant frequency ωₜᵣₐₚ. As more ferromagnetic conductive material is inserted into the dielectric formers 62, the trap resonant frequency ωₜᵣₐₚ decreases. When ferromagnetic conductive material is used for tuning, the capacitance of the capacitor 74 should be selected to be small enough to ensure that the trap resonant frequency is larger than the desired trap resonant frequency value before insertion of any ferromagnetic conductive material into the formers 62.

When the butterfly trap 60 is arranged in the main B₀ magnetic field, it is advantageous to have the trap 60 balanced to reduce external magnetic fields. Thus, the number of dielectric formers 62 is preferably even. For example, two formers 62 can be used as illustrated. The coaxial cable 66 is wrapped in oppositely directed helices on the two dielectric formers 62 to produce anti-parallel magnetic fields in the two formers 62. Moreover, an equal amount of the electrically conductive tuning material is preferably inserted into each of the two formers 62 to maintain field-balancing in the fine-tuned butterfly trap.

In one embodiment, the bobbins 62 are fastened to the printed circuit board 78 using either electrically conductive screws 84, or electrically insulating screws 85 (for example, Teflon screws), or some combination of electrically conductive screws 84 and electrically insulating screws 85. The electrically conductive screws 84 and the electrically insulating screws 85 are mechanically interchangeable.

As shown in FIGS. 6 and 7, each bobbin 62 is secured to the printed circuit board 78 by two screws, which can be two electrically conductive screws 84 as shown in FIG. 7, or can be two electrically insulating screws, can be two electrically conducting screws of different length, or can be one electrically conductive screw 84 and one electrically insulating screw 85, as shown in FIG. 6. By selecting among screws of different length and gauges a large number of corresponding selectable tuning values can be achieved. For example, the screws can vary in length from about a half centimeter to two centimeters. For fine tuning, small amounts can be ground off the end of one of the screws, or one of the screws can be incompletely inserted.

Additional levels of tuning can be provided by using three, four, or more screws for securing each bobbin 62, and selecting from amongst electrically conductive screws 84 and electrically insulating screws 85 to control the total amount of electrically conductive material inserted into the bobbins 62. In another contemplated, embodiment, composite screws that have varying amounts of electrically conductive material are used to provide still further levels of fine tuning of the trap resonance frequency.

The embodiment of FIGS. 2-7 has the advantage that the fasteners already used to fasten the radio frequency trap 60 to the printed circuit board 78 are additionally used to selectably fine tune the frequency of the butterfly trap 60.

With reference to FIGS. 8 and 9, another embodiment of the balanced radio frequency butterfly trap 60′ is illustrated. In FIGS. 8 and 9, components that are unchanged from the trap 60 of FIGS. 2-7 are labeled with the same reference numbers, while modified components are labeled with corresponding primed reference numbers. New components are labeled with new reference numbers.

In the butterfly trap 60′, the coaxial cable 64 is wrapped around modified dielectric formers or bobbins 62′ to form modified inductive element 66′. In one embodiment, the bobbins 62′ are generally cylindrical and each include a helical slot 70′ formed into the cylindrical surface of the bobbin 62′. The capacitor is suitably the same capacitor 74 as in the trap 60, and is not shown in FIGS. 8 and 9. The trap 60′ is secured to the printed circuit board 78 using fasteners (not shown) that are either not electrically conductive or which do not insert into the formers 62′. In another variation, the fasteners are electrically conductive and do insert into the formers 62′, but are always electrically conductive. In any of these cases, the fasteners are not used for fine tuning the butterfly trap 60′.

Instead, fine tuning is achieved by selectively inserting electrically conductive rods or dowels 90 into openings 92 formed into the dielectric formers 62′. In FIG. 8, three tuning rods 90 are inserted into each bobbin 62′, while three other tuning rods 90 are shown aligned for insertion into each bobbin 62′. Advantageously, the rods or dowels 90 can be inserted or removed without partially or entirely unfastening the butterfly trap 60′ from the printed circuit board 78. Moreover, if less electrically conductive material is needed, then some electrically conductive rods or dowels 90 are omitted, leaving the corresponding openings 92 unfilled. There is generally no need to insert dummy insulating dowels into these openings. Moreover, the number of openings is not tied to the number of mechanical fasteners. As illustrated in FIGS. 8 and 9, a relatively large number of openings 92 can be provided to provide a large number of fine tuning levels for the butterfly trap 60′.

Analogously to the trap 60 of FIGS. 2-7, the electrically conductive rods or dowels 90 can be non-ferromagnetic or, if the environment is non-magnetic, can be ferromagnetic. Non-ferromagnetic dowels reduce the inductance and increase the resonance frequency, while ferromagnetic dowels increase the inductance and reduce the resonance frequency.

When using either non-ferromagnetic or ferromagnetic electrically conductive material to tune the trap 60, 60′, the effective amount of electrically conductive material needed for tuning a particular trap to a particular desired resonance frequency can be determined in various ways. The trap resonance can be measured electrically by connecting a suitable radio frequency probe to the connection ends 80 of the trap 60. Rods 90 can be advanced into the bobbins 62′ until the target resonance frequency is reached. When the target resonance frequency is reached with one of the rods only partially inserted, the rod is optionally shortened or replaced by a shorter rod accordingly.

Alternatively, if the tolerance of the capacitor 74 is substantially larger than the tolerance of the inductive element 66, 66′, then the capacitance of the capacitor 74 largely controls the trap resonance frequency. In this case, the effective amount of material can be calibrated with respect to the capacitance of the capacitor 74, either empirically or by computing the resonance frequency for the specific trap topology and inductance, for example with reference to Equation (1). In yet another approach, the trap 60, 60′ can be tuned after installation in the magnetic resonance scanner 10, for example by excitation of the radio frequency coil via the trap 60, 60′. Once tuned, the rods are optionally cemented into place with epoxy or the like.

In the radio frequency trap 60′ of FIGS. 8 and 9, it is contemplated to calibrate then number of tuning rods 90 that need to be inserted into a particular trap to obtain various resonance frequencies. Once this is done, a user can fine tune the trap to different pre-determined frequencies merely by adding, removing, or shortening, tuning rods 90. Thus, for example, the trap can be selectively fine tuned to different magnetic resonance frequencies to accommodate different main B₀ magnetic fields, different proton resonance systems, and the like.

While balanced butterfly radio frequency traps are illustrated, the fine tuning approach is suitably applied to radio frequency traps including a single dielectric former or more than two dielectric formers. Moreover, a helical cable alignment slot similar to the helical slots 70, 70′ can be included on each former in traps employing a single former or more than two formers. Other electrically conductive tuning elements besides the illustrated fastening screws 84 or rods 90 can be inserted into the bobbins to provide fine tuning in accordance with the fine tuning processed disclosed herein.

If the trap is being used outside of a magnetic environment, then it may be acceptable to use an unbalanced trap. For example, a trap topology other than the butterfly topology can be employed in such cases. Moreover, if the trap is being used outside of a magnetic environment, then a combination of ferromagnetic conductive material and non-ferromagnetic conductive material can be inserted into the bobbin or bobbins to selectively reduce or increase the radio frequency trap resonance frequency.

Furthermore, while the embodiments are described with reference to a magnetic resonance imaging system, it will be appreciated that the radio frequency traps and trap tuning processes disclosed herein are generally applicable to other applications employing radio frequency excitations and signals.

The invention has been described with reference to the preferred embodiments. Obviously, modifications and alterations will occur to others upon reading and understanding the preceding detailed description. It is intended that the invention be construed as including all such modifications and alterations insofar as they come within the scope of the appended claims or the equivalents thereof.

Having described the preferred embodiments, the invention is now claimed to be:

1. A method for tuning a radio frequency trap having an inductive element including a dielectric former and a coaxial cable wrapped around the former, the method comprising:
inserting an effective amount of electrically conductive material into the dielectric former, the amount being effective to adjust an inductance of the inductive element to tune the radio frequency trap to a selected resonant frequency value.

2. The method as set forth in claim 1, further comprising:
electrically connecting a capacitance across the inductive element, the capacitance cooperating with the inductive element to produce an untuned resonant frequency smaller than the selected resonant frequency value.

3. The method as set forth in claim 2, wherein the inserting of an effective amount of electrically conductive material comprises:
inserting non-ferromagnetic electrically conductive material into the dielectric former until the untuned resonant frequency is increased to the selected resonant frequency value.

4. The method as set forth in claim 1, wherein the electrically conductive material is ferromagnetic, the method further comprising:
electrically connecting a capacitance across the inductive element, the capacitance cooperating with the inductive element to produce an untuned resonant frequency larger than a desired resonant frequency, the inserting including inserting ferromagnetic electrically conductive material until the untuned resonant frequency is decreased to the selected resonant frequency value.

5. The method as set forth in claim 1, wherein the inductive element includes two dielectric formers and the coaxial cable is wrapped around the two dielectric formers in oppositely directed helices to produce anti-parallel magnetic fields in the two dielectric formers, and the inserting of an electrically conductive material into the dielectric former comprises:
inserting substantially the same amount of conductive material into each dielectric former.

6. The method as set forth in claim 1, wherein the inductive element includes two dielectric formers and the coaxial cable is wrapped around the two dielectric formers in a balanced radio frequency butterfly trap topology, and the inserting of an electrically conductive material into the dielectric former comprises:
inserting one or more rods, each rod including electrically conductive material, into openings formed into each of the dielectric formers.

7. The method as set forth in claim 1, wherein the inserting of an electrically conductive material into the dielectric former comprises:
fastening the radio frequency trap to a substrate using one or more fasteners that fasten to the dielectric former, the fasteners including the electrically conductive material.

8. The method as set forth in claim 7, wherein the radio frequency trap is a balanced butterfly trap including an even number of dielectric formers and the fastening of the radio frequency trap comprises:
fastening the same number of electrically conductive fasteners to each dielectric former.

9. The method as set forth in claim 8, further comprising:
fastening one or more other fasteners to each dielectric former, the one or more other fasteners also contributing to the securing of the radio frequency trap to the substrate, each of the other fasteners not including electrically conductive material.

10. The method as set forth in claim 8, wherein lengths of the one or more fasteners are selected to adjust the inductance of the inductive element.

11. A radio frequency trap comprising:
one or more dielectric formers;
a cable including an inner conductor and a coaxial outer conductor, at least a portion of the cable being wrapped around the one or more dielectric formers, the coaxial outer conductor of the portion of the cable wrapped around the one or more dielectric formers defining at least one inductive element;
a capacitance connected across the at least one inductive element; and
a selected amount of electrically conductive material inserted into the one or more dielectric formers, the selected amount of electrically conductive material cooperating with the at least one inductive element and the capacitance to define a resonant circuit having a selected resonance frequency.

12. The radio frequency trap as set forth in claim 11, wherein the one or more dielectric formers are each generally cylindrical with a corkscrew slot formed into the cylindrical surface, the wrapped cable being received by the corkscrew slot.

13. The radio frequency trap as set forth in claim 11, wherein the selected amount of electrically conductive material is embodied in fasteners for mounting the dielectric former to a support structure.

14. An apparatus comprising:
a radio frequency trap including at least:
an even number of dielectric formers,
a coaxial cable wrapped around the dielectric formers, and
a plurality of tuning elements selectively inserted into the dielectric formers to tune the radio frequency trap to a selected resonance frequency.

15. The apparatus as set forth in claim 14, further comprising:
a magnetic resonance imaging scanner including at least a main magnet generating a spatially uniform main magnetic field at least over a field of view, a plurality of gradient coils selectively generating magnetic field gradients at least over the field of view, and a radio frequency coil for performing at least one of exciting and detecting magnetic resonance at the selected resonance frequency in an imaging subject disposed in the field of view; wherein
the radio frequency trap is connected with the radio frequency coil of the magnetic resonance imaging scanner to provide common mode high impedance to radio frequency current flow in the radio frequency coil.

16. The apparatus as set forth in claim 14, wherein the number of dielectric formers is two.

17. The apparatus as set forth in claim 16, wherein the tuning elements comprise:
tuning fasteners each including a preselected amount of electrically conductive material that fasten the radio frequency trap to a substrate.

18. The apparatus as set forth in claim 17, further comprising:
non-tuning fasteners not including electrically conductive material, the radio frequency trap being secured to the substrate by a selected number of fasteners including at least one tuning fastener and one non-tuning fastener inserted into each of the two dielectric formers.

19. The apparatus as set forth in claim 16, wherein the radio frequency trap has the same number of tuning elements inserted into each of the two dielectric formers.

20. The apparatus as set forth in claim 14, wherein each dielectric former is generally cylindrical with a corkscrew slot formed into the cylindrical surface, the wrapped coaxial cable being received by the corkscrew slot.

21. A radio frequency trap comprising:
one or more dielectric formers;
a cable including an inner conductor and a coaxial outer conductor, at least a portion of the cable being wrapped around the one or more dielectric formers, the coaxial outer conductor of the portion of the cable wrapped around the one or more dielectric formers defining at least one inductive element;
a capacitance connected across the at least one inductive element; and
one or more electrically conductive fasteners securing the one or more dielectric formers to a substrate wherein at least a portion of each electrically conductive fastener is disposed inside the dielectric former to which it fastens.

22. The radio frequency trap as set forth in claim 21, further including:
one or more electrically insulating fasteners securing the one or more dielectric formers to a substrate, the electrically conductive fasteners and the electrically insulating fasteners being mechanically interchangeable.
